(19) United States
(12) Patent Application Publication
(10) Pub. No.: US 2025/0062177 A1
(43) Pub. Date: Feb. 20, 2025

(54) SEMICONDUCTOR PACKAGE

(71) Applicant: SAMSUNG ELECTRONICS CO., LTD., Suwon-si (KR)

(72) Inventors: Han Min LEE, Suwon-si (KR); Sang-Sick PARK, Suwon-si (KR); Un-Byoung KANG, Suwon-si (KR); Ku Young KIM, Suwon-si (KR)

(21) Appl. No.: 18/623,860

(22) Filed: Apr. 1, 2024

(30) Foreign Application Priority Data
Aug. 18, 2023 (KR) 10-2023-0108114

(51) Int. Cl. H01L 23/31; H01L 21/56; H01L 23/00; H01L 25/00; H01L 25/065; H01L 25/18

(52) U.S. Cl. CPC H01L 23/3192; H01L 21/563; H01L 24/16; H01L 24/17; H01L 24/29; H01L 24/32; H01L 24/33; H01L 24/73; H01L 25/0657; H01L 25/18; H01L 24/81; H01L 24/83; H01L 24/92; H01L 25/50; H01L 2224/0557; H01L 2224/06181; H01L 2224/16145; H01L 2224/16227; H01L 2224/17181; H01L 2224/29016; H01L 2224/32013; H01L 2224/32145; H01L 2224/32225; H01L 2224/33181; H01L 2224/73104; H01L 2224/73204; H01L 2224/73253; H01L 2224/81191; H01L 2224/81201; H01L 2224/83191; H01L 2224/83201; H01L 2224/83862; H01L 2224/9211; H01L 2225/06513; H01L 2225/06517; H01L 2225/06541; H01L 2225/06565; H01L 2924/1431; H01L 2924/1433; H01L 2924/14335; H01L 2924/1436; H01L 2924/1437; H01L 2924/1441; H01L 2924/1443

(57) ABSTRACT

A semiconductor package includes a base substrate, a first semiconductor chip on the base substrate, a second semiconductor chip on the first semiconductor chip, an upper pad on an upper surface of the first semiconductor chip, a lower pad on a lower surface of the second semiconductor chip that faces the upper surface of the first semiconductor chip, a connecting bump between the upper pad and the lower pad, a lower film on the upper surface of the first semiconductor chip, and on a side surface of the upper pad and an upper film between the lower film and the lower surface of the second semiconductor chip, and on a side surface of the lower pad, wherein the lower film includes a thermosetting material, the upper film includes a photocurable material, and a side surface of the lower film protrudes outward beyond a side surface of the first semiconductor chip.

### CROSS-REFERENCE TO RELATED APPLICATION

This application claims priority from Korean Patent Application No. 10-2023-0108114 filed on Aug. 18, 2023 in the Korean Intellectual Property Office, and all the benefits accruing therefrom under 35 U.S.C. 119, the disclosure of which is incorporated herein by reference in its entirety.

### BACKGROUND

### 1. Field of the Disclosure

The present disclosure relates to a semiconductor package.

### 2. Description of the Related Art

With the development of the electronic industry, demands for higher functionality, higher speed, and smaller size of electronic components are increasing. In response to this trend, a method for stacking and mounting a plurality of semiconductor chips on a single package wiring structure, or a method for stacking packages on top of each other may be used.

In semiconductor packaging, a non-conductive film (NCF) is used between multiple semiconductor chips. As the electronic components become smaller, problems such as warpage due to non-conductive film inside the semiconductor package may arise.

### SUMMARY

Aspects of the present disclosure provide a semiconductor package having improved product reliability.

Aspects of the present disclosure also provide a method for fabricating a semiconductor package that may fabricate the semiconductor package having improved product reliability.

According to an aspect of the present disclosure, there is provided a semiconductor package comprising a base substrate, a first semiconductor chip on the base substrate, a second semiconductor chip on the first semiconductor chip, an upper pad on an upper surface of the first semiconductor chip, a lower pad on a lower surface of the second semiconductor chip, wherein the lower surface of the second semiconductor chip faces the upper surface of the first semiconductor chip, a connecting bump between the upper pad and the lower pad, a lower film on the upper surface of the first semiconductor chip, and on a side surface of the upper pad, and an upper film between the lower film and the lower surface of the second semiconductor chip, and on a side surface of the lower pad, wherein the lower film includes a thermosetting material, the upper film includes a photocurable material, and a side surface of the lower film protrudes outward beyond a side surface of the first semiconductor chip.

According to an aspect of the present disclosure, there is provided a semiconductor package comprising a base substrate, a first semiconductor chip on the base substrate, a second semiconductor chip on the first semiconductor chip, a first upper pad on a upper surface of the first semiconductor chip, a first lower pad on a lower surface of the second semiconductor chip, wherein the lower surface of the second semiconductor chip faces the upper surface of the first semiconductor chip, a first connecting bump between the first upper pad and the first lower pad, a first lower film on the upper surface of the first semiconductor chip, and on a side surface of the first upper pad, wherein the first lower film includes a thermosetting material, and a first upper film between the first lower film and the lower surface of the second semiconductor chip, and on a side surface of the first lower pad, wherein the first upper film includes a photocurable material, and wherein a maximum width of the first lower film is greater than a maximum width of the first upper film.

According to an aspect of the present disclosure, there is provided a semiconductor package comprising a base substrate, a first semiconductor chip on the base substrate, a second semiconductor chip on the first semiconductor chip, a first upper pad on a upper surface of the first semiconductor chip, a first lower pad on a lower surface of the second semiconductor chip, wherein the lower surface of the second semiconductor chip faces the upper surface of the first semiconductor chip, a first connecting bump between the first upper pad and the first lower pad, a first lower film on the upper surface of the first semiconductor chip, and on a side surface of the first upper pad, wherein the first lower film includes a thermosetting material, a first upper film between the first lower film and a lower surface of the second semiconductor chip, and on a side surface of the first lower pad, wherein the first upper film includes a photocurable material, and a molding film on the base substrate, the first semiconductor chip, and the second semiconductor chip, wherein a side surface of the first upper film is coplanar with a side surface of the second semiconductor chip, a side surface of the first lower film protrudes outward beyond the side surface of the first upper film, and an upper surface of the first lower film is below a lower surface of the first lower pad.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram showing a semiconductor package according to some embodiments.

FIG. 2 is an enlarged view of a portion P of FIG. 1.

FIG. 3 is a diagram for explaining a semiconductor package according to some other embodiments.

FIG. 4 is an enlarged view of a portion Q of FIG. 3.

FIG. 5 is a diagram for explaining a semiconductor package according to some other embodiments.

FIG. 6 is an enlarged view showing a portion R of FIG. 5.

FIGS. 7 to 15 are intermediate stage diagrams showing a method for fabricating a semiconductor package according to some embodiments.

FIGS. 16 and 17 are diagrams of intermediate steps for explaining a method for fabricating a semiconductor package according to some other embodiments.

### DETAILED DESCRIPTION OF THE EMBODIMENTS

Embodiments according to the technical idea of the present disclosure will be described below with reference to the accompanying drawings.

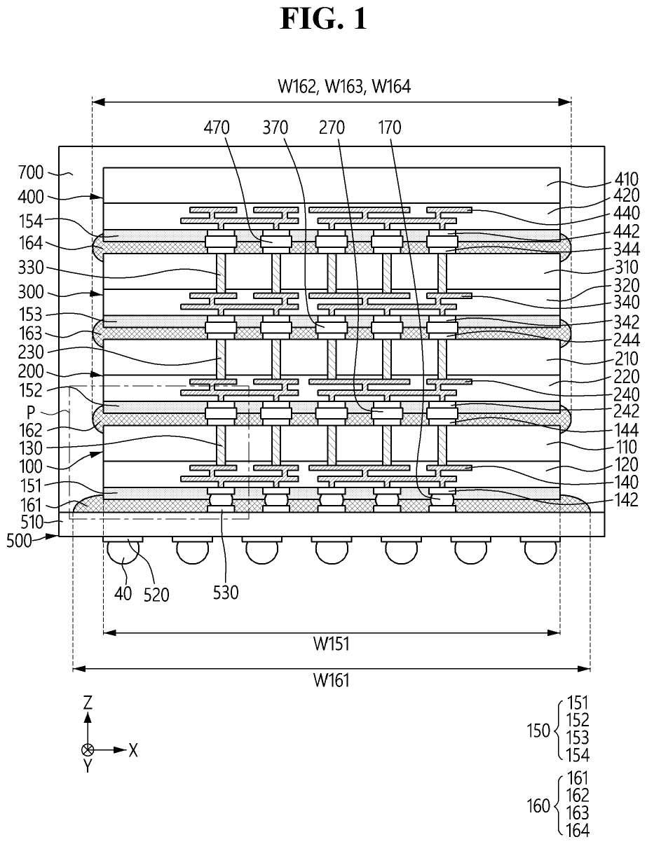

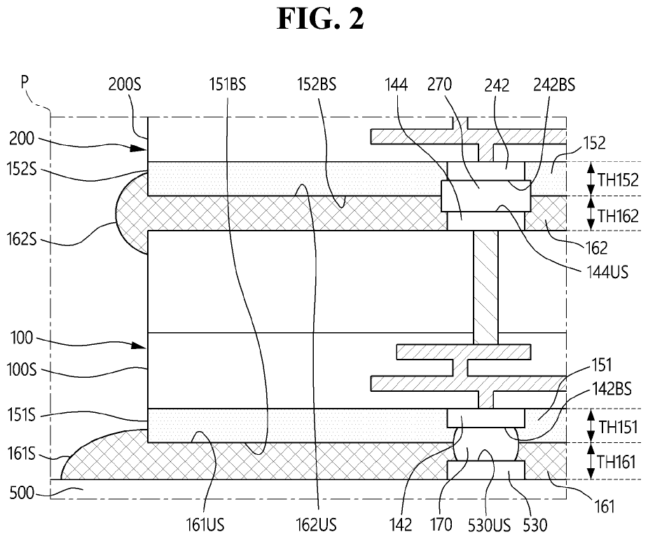

FIG. 1 is a diagram showing a semiconductor package according to some embodiments. FIG. 2 is an enlarged view of a portion P of FIG. 1.

Referring to FIGS. 1 and 2, the semiconductor device may include first to fourth semiconductor chips 100 to 400, an upper film 150, a lower film 160, a base substrate 500 and a molding film 700.

The first to fourth semiconductor chips 100 to 400 may be logic chips or memory chips. The first to fourth semiconductor chips 100 to 400 may all be memory chips of the same type. For example, the first to fourth semiconductor chips 100 to 400 may be a volatile memory chip such as a DRAM (Dynamic Random Access Memory) or an SRAM (Static Random Access Memory). As another example, the first to fourth semiconductor chips 100 to 400 may be a nonvolatile memory chip such as a PRAM (Phase-change RAM), a MRAM (Magnetoresistive RAM), a FeRAM (Ferroelectric RAM) or a RRAM (Resistive RAM) n. As another example, the first to fourth semiconductor chips 100 to 400 may be a HBM (High Bandwidth Memory).

Furthermore, some of the first to fourth semiconductor chips 100 to 400 may be memory chips, and some others may be logic chips. For example, some of the first to fourth semiconductor chips 100 to 400 may be microprocessors, analog elements, digital signal processors or application processors.

The first to fourth semiconductor chips 100 to 400 may be stacked on the base substrate 500 in a vertical direction. The first to fourth semiconductor chips 100 to 400 may be electrically connected to each other through the first to fourth connecting bumps 170, 270, 370, and 470 or may be electrically connected to the base substrate 500.

The first to fourth semiconductor chips 100 to 400 and the base substrate 500 may be attached to each other by a non-conductive film (NCF). The upper film 150 and the lower film 160 may be disposed between the first to fourth semiconductor chips 100 to 400 and the base substrate 500, respectively.

The upper film 150 may include a first upper film to a fourth upper film 151 to 154. The lower film 160 may include first to fourth lower films 161 to 164.

The upper film 150 and the lower film 160 may each include different materials. The upper film 150 may include a photocurable material. For example, the upper film 150 may include a material that is cured by ultraviolet ray (UV). Each of the first to fourth upper films 151 to 154 may include a photocurable material. The lower film 160 may include a thermoset material. For example, the lower film 160 may include a thermoset material in which viscosity varies at a specific temperature. Each of the first to fourth lower films 161 to 164 may include a photocurable material.

The first upper film 151 and the first lower film 161 may be disposed between the base substrate 500 and the first semiconductor chip 100. The first upper film 151 and the first lower film 161 may fill the space between the base substrate 500 and the first semiconductor chip 100. The first upper film 151 and the first lower film 161 may attach the base substrate 500 and the first semiconductor chip 100 together.

The first upper film 151 may be disposed on the lower surface of the first semiconductor chip 100. The first upper film 151 may extend along the lower surface of the first semiconductor chip 100. The first upper film 151 may cover the lower surface of the first semiconductor chip 100. The first upper film 151 may be disposed between the upper surface of the first lower film 161 and the lower surface of the first semiconductor chip 100. The first upper film 151 may fill the space between the upper surface of the first lower film 161 and the lower surface of the first semiconductor chip 100.

The first lower film 161 may be disposed on the upper surface of the base substrate 500. The first lower film 161 may extend along the upper surface of the base substrate 500. The first lower film 161 may cover the upper surface of the base substrate 500. The first lower film 161 may be disposed between a lower surface 151BS of the first upper film and the upper surface of the base substrate 500. The first lower film 161 may fill the space between the first upper film 151 and the upper surface of the base substrate 500.

A width W151 of the first upper film may be the same as a width of the first semiconductor chip 100. A side surface 151S of the first upper film may be coplanar with a side surface 100S of the first semiconductor chip. The side surface 151S of the first upper film may overlap the side surface 100S of the first semiconductor chip in a third direction Z. The side surface 151S of the first upper film may be perpendicularly aligned with the side surface 100S of the first semiconductor chip.

A width W161 of the first lower film may be greater than the width W151 of the first upper film. The width W161 of the first lower film may be greater than the width of the first semiconductor chip 100. A side surface 161S of the first lower film may protrude outward beyond the side surface 151S of the first upper film. Specifically, in a first direction X, the side surface 161S of the first lower film may protrude further from the side surface 100S of the first semiconductor chip than the side surface 151S of the first upper film. The side surface 161S of the first lower film may not be coplanar with the side surface 100S of the first semiconductor chip.

The first lower film 161 may cover a part of the side surface 151S of the first upper film. The first lower film 161 may overlap the side surface 151S of the first upper film in the first direction X. The uppermost point of the first lower film 161 may be located above the lower surface 151BS of the first upper film.

The first lower film 161 may not cover the side surface 100S of the first semiconductor chip. The first lower film 161 may not be in contact with the side surface 100S of the first semiconductor chip. The first lower film 161 may not overlap the side surface 100S of the first semiconductor chip. The first lower film 161 may protrude outward beyond the side surface 100S of the first semiconductor chip in the first direction X.

The first lower film 161 may not cover the side surfaces of the base substrate 500. The first lower film 161 may be disposed on the upper surface of the base substrate 500.

The first upper film 151 may cover a first lower connecting pad 142. The first upper film 151 may surround the side surfaces of the first lower connecting pad 142. The lower surface 151BS of the first upper film may be located below the lower surface 142BS of the first lower connecting pad. The first upper film 151 may completely overlap the first lower connecting pad 142 in the first direction X. A thickness TH151 of the first upper film may be greater than a thickness of the first lower connecting pad 142.

A contact face between the first connecting bump 170 and the first lower connecting pad 142 may be disposed inside the first upper film 151. The contact face between the first connecting bump 170 and the first lower connecting pad 142 may be disposed between the lower surface of the first semiconductor chip 100 and the lower surface 151BS of the first upper film in the third direction Z.

The first upper film 151 may not overlap an upper pad 530 in the first direction X. The lower surface 151BS of the first upper film may be located above the upper surface 530US of the upper pad. The first upper film 151 may not be in contact with the upper pad 530.

The first upper film 151 may cover a part of the side surface of the first connecting bump 170. The lower surface 151BS of the first upper film may be disposed between the upper surface and the lower surface of the first connecting bump 170. The first upper film 151 may not completely overlap the first connecting bump 170 in the first direction X. The first upper film 151 overlaps a part of the first connecting bump 170 in the first direction X, and the first upper film 151 may not overlap the remaining part of the first connecting bump 170 in the first direction X.

In FIG. 1, although the width W151 of the first upper film is shown as being the same as a width W162 of the second upper film, a width W163 of the third upper film, and a width W164 of the fourth upper film, the embodiment is not limited thereto. For example, the width W151 of the first upper film may be greater than the width W162 of the second upper film, the width W163 of the third upper film, and the width W164 of the fourth upper film. As another example, the width W151 of the first upper film may be smaller than the width W162 of the second upper film, the width W163 of the third upper film, and the width W164 of the fourth upper film.

The first lower film 161 may cover the upper pad 530. The first lower film 161 may surround the side surface of the upper pad 530. An upper surface 161US of the first lower film may be located above the upper surface 530US of the upper pad. The upper surface 161US of the first lower film may refer to a face that is in contact with the first upper film 151 between the base substrate 500 and the first semiconductor chip 100. The first lower film 161 may completely overlap the upper pad 530 in the first direction. A thickness TH161 of the first lower film may be greater than the thickness of the upper pad 530. A contact face between the first connecting bump 170 and the upper pad 530 may be disposed inside the first lower film 161. The contact face between the first connecting bump 170 and the upper pad 530 may be disposed between the upper surface 161US of the first lower film and the upper surface of the base substrate 500 in the third direction Z.

The first lower film 161 may not overlap the first lower connecting pad 142 in the first direction X. The upper surface 161US of the first lower film may be located below the lower surface 142BS of the first lower connecting pad. The first lower film 161 may not be in contact with the first lower connecting pad 142.

The first lower film 161 may cover a part of the side surface of the first connecting bump 170. The upper surface 161US of the first lower film may be disposed between the upper surface and the lower surface of the first connecting bump 170. The first lower film 161 may not completely overlap the first connecting bump 170 in the first direction X. The first lower film 161 overlaps a part of the first connecting bump 170 in the first direction X, and the first lower film 161 may not overlap the remaining part of the first connecting bump 170 in the first direction X.

The width W161 of the first lower film may be greater than the width W162 of the second lower film, the width W163 of the third lower film, and the width W164 of the fourth lower film. For example, the side surface 161S of the first lower film may protrude outward beyond the side surface 162S of the second lower film.

Although FIGS. 1 and 2 show that the width W161 of the first lower film is greater than the width W162 of the second lower film, the width W163 of the third lower film, and the width W164 of the fourth lower film, embodiments are not limited thereto. For example, the width W161 of the first lower film may be the same as the width W162 of the second lower film, the width W163 of the third lower film, and the width W164 of the fourth lower film. As another example, the width W161 of the first lower film may be smaller than the width W162 of the second lower film, the width W163 of the third lower film, and the width W164 of the fourth lower film.

The second upper film 152 and the second lower film 162 may be disposed between the first semiconductor chip 100 and a second semiconductor chip 200. The second upper film 152 and the second lower film 162 may fill the space between the first semiconductor chip 100 and the second semiconductor chip 200. The second upper film 152 and the second lower film 162 may attach the first semiconductor chip 100 and the second semiconductor chip 200 to each other.

The second upper film 152 may be disposed on the lower surface of the second semiconductor chip 200. The second upper film 152 may extend along the lower surface of the second semiconductor chip 200. The second upper film 152 may cover the lower surface of the second semiconductor chip 200. The second upper film 152 may be disposed between the upper surface of the second lower film 162 and the lower surface of the second semiconductor chip 200. The second upper film 152 may fill the space between the upper surface of the second lower film 162 and the lower surface of the second semiconductor chip 200.

The second lower film 162 may be disposed on the upper surface of the first semiconductor chip 100. The second lower film 162 may extend along the upper surface of the first semiconductor chip 100. The second lower film 162 may cover the upper surface of the first semiconductor chip 100. The second lower film 162 may be disposed between the lower surface of the second upper film 152 and the upper surface of the first semiconductor chip 100. The second lower film 162 may fill the space between the second upper film 152 and the upper surface of the first semiconductor chip 100.

The width of the second upper film 152 may be the same as the width of the second semiconductor chip 200. The side surface 152S of the second upper film may be coplanar with the side surface 200S of the second semiconductor chip. The side surface 152S of the second upper film may overlap the side surface 200S of the second semiconductor chip in the third direction Z. The side surface 152S of the second upper film may be vertically aligned with the side surface 200S of the second semiconductor chip.

A width W162 of the second lower film may be greater than the width of the second upper film 152. The width W162 of the second lower film may be greater than the width of the second semiconductor chip 200. The side surface 162S of the second lower film may protrude outward beyond the side surface 152S of the second upper film. Specifically, in the first direction X, the side surface 162S of the second lower film may protrude further from the side surface 200S of the second semiconductor chip than the side surface 152S of the second upper film. The side surface 162S of the second lower film may not be coplanar with the side surface 200S of the second semiconductor chip.

The second lower film 162 may cover a part of the side surface 152S of the second upper film. The second lower film 162 may overlap the side surface 152S of the second upper film in the first direction X. The uppermost point of the second lower film 162 may be located above the lower surface of the second upper film 152.

The second lower film 162 may not cover the side surface 200S of the second semiconductor chip. The second lower film 162 may not be in contact with the side surface 200S of the second semiconductor chip. The second lower film 162 may overlap the side surface 200S of the second semiconductor chip. The second lower film 162 may protrude outward beyond the side surface 200S of the second semiconductor chip in the first direction X.

The second lower film 162 may cover a part of the side surface 100S of the first semiconductor chip. The second lower film 162 may overlap the side surface 100S of the first semiconductor chip in the first direction X. The lowermost point of the second lower film 162 may be located below the upper surface of the first semiconductor chip 100.

The second upper film 152 may cover the second lower connecting pad 242. The second upper film 152 may surround the side surfaces of the second lower connecting pad 242. The lower surface 152BS of the second upper film may be located below the lower surface 242BS of the second lower connecting pad. The second upper film 152 may completely overlap the second lower connecting pad 242 in the first direction. A thickness TH152 of the second upper film may be greater than the thickness of the second lower connecting pad 242.

A contact face between the second connecting bump 270 and the second lower connecting pad 242 may be disposed inside the second upper film 152. The contact face between the second connecting bump 270 and the second lower connecting pad 242 may be disposed between the lower surface of the second semiconductor chip 200 and the lower surface 152BS of the second upper film in the third direction Z.

The second upper film 152 may not overlap the first upper connecting pad 144 in the first direction X. The lower surface 152BS of the second upper film may be located above the upper surface 144US of the first upper connecting pad. The second upper film 152 may not be in contact with the first upper connecting pad 144.

The second upper film 152 may cover a part of the side surface of the second connecting bump 270. The lower surface 152BS of the second upper film may be disposed between the upper surface and the lower surface of the second connecting bump 270. The second upper film 152 may not completely overlap the second connecting bump 270 in the first direction X. The second upper film 152 overlaps a part of the second connecting bump 270 in the first direction X, and the second upper film 152 may not overlap the remaining part of the second connecting bump 270 in the first direction X.

The second lower film 162 may cover the first upper connecting pad 144. The second lower film 162 may surround the side surfaces of the first upper connecting pad 144. An upper surface 162US of the second lower film may be located above the upper surface 144US of the first upper connecting pad. The upper surface 162US of the second lower film may refer to a face that is in contact with the second upper film 152 between the first semiconductor chip 100 and the second semiconductor chip 200. The second lower film 162 may completely overlap the first upper connecting pad 144 in the first direction X. A thickness TH162 of the second lower film may be greater than the thickness of the first upper connecting pad 144.

The second lower film 162 may not overlap the second lower connecting pad 242 in the first direction X. The upper surface 162US of the second lower film may be located below the lower surface 242BS of the second lower connecting pad. The second lower film 162 may not be in contact with the second lower connecting pad 242.

The second lower film 162 may cover a part of the side surface of the second connecting bump 270. The upper surface 162US of the second lower film may be located between the upper surface and the lower surface of the second connecting bump 270. The second lower film 162 may not completely overlap the second connecting bump 270 in the first direction X. The second lower film 162 overlaps a part of the second connecting bump 270 in the first direction X, and the second lower film 162 may not overlap the remaining part of the second connecting bump 270 in the first direction X.

The third upper film 153 and the third lower film 163 may be disposed between the second semiconductor chip 200 and a third semiconductor chip 300. The third upper film 153 and the third lower film 163 may fill the space between the second semiconductor chip 200 and the third semiconductor chip 300. The third upper film 153 and the third lower film 163 may attach the second semiconductor chip 200 and the third semiconductor chip 300 to each other.

The fourth upper film 154 and the fourth lower film 164 may be disposed between the third semiconductor chip 300 and a fourth semiconductor chip 400. The fourth upper film 154 and the fourth lower film 164 may fill the space between the third semiconductor chip 300 and the fourth semiconductor chip 400. The fourth upper film 154 and the fourth lower film 164 may attach the third semiconductor chip 300 and the fourth semiconductor chip 400 to each other.

The description of the third upper film 153 and the fourth upper film 154 may be substantially the same as the description of the first upper film 151 and the second upper film 152, and therefore will be omitted. The description of the third lower film 163 and the fourth lower film 164 may be substantially the same as the description of the first lower film 161 and the second lower film 162, and therefore will be omitted.

Although four first to fourth semiconductor chips 100 to 400 are shown as being stacked in FIG. 1, the embodiment is not limited thereto. For example, a semiconductor package may include semiconductor chips stacked in different numbers, such as one or two.

The first semiconductor chip 100 may include a first semiconductor substrate 110, a first semiconductor element layer 120, a first through electrode 130, a first lower connecting pad 142, a first upper connecting pad 144, and a first connecting bump 170.

The first semiconductor substrate 110 may be, for example, bulk silicon or silicon-on-insulator (SOI). As another example, the first semiconductor substrate 110 may be a silicon substrate. As still another example, the first semiconductor substrate 110 may include, but not limited to, silicon germanium, silicon germanium on insulator (SGOI), indium antimonide, lead telluride, indium arsenide, indium phosphide, gallium arsenide or gallium antimonide.

The first semiconductor substrate 110 may include a conductive region, for example, an impurity-doped well or an impurity-doped structure. The first semiconductor substrate 110 may have various element separation structures, such as a shallow trench isolation (STI) structure.

The first semiconductor element layer 120 may be disposed on the lower surface of the first semiconductor substrate 110. The first semiconductor element layer 120 may include a plurality of various types of individual devices and an interlayer insulating film. The individual devices include various microelectronic devices, for example, a MOSFET (metal-oxide-semiconductor field effect transformer) such as a CMOS transistor (complementary metal-insulator-semiconductor transistors), a system LSI (large scale integration), a flash memory, a DRAM, an SRAM, an EEPROM, a PRAM, a MRAM, a RRAM, an image sensor such as a CIS (CMOS imaging sensor), a MEMS (micro-electro-mechanical system), an active device, a passive device, etc.

The individual devices of the first semiconductor element layer 120 may be electrically connected to a conductive region formed inside the first semiconductor substrate 110. The individual devices of the first semiconductor element layer 120 may be electrically separated from other adjacent individual devices by insulating films. The first semiconductor element layer 120 may include a first wiring structure 140 that electrically connects at least two of the plurality of individual devices or a plurality of individual devices to the conductive region of the first semiconductor substrate 110.

Although not shown, a lower passivation layer for protecting structures different from the first wiring structure 140 in the first semiconductor element layer 120 from external impact and moisture may be formed on the first semiconductor element layer 120. The lower passivation layer may expose a part of the upper surface of the first lower connecting pad 142.

The first through electrode 130 may penetrate the first semiconductor substrate 110. The first through electrode 130 may extend from the upper surface of the first semiconductor substrate 110 toward the lower surface. The first through electrode 130 may be connected to the first wiring structure 140 provided inside the first semiconductor element layer 120.

The first through electrode 130 may include a barrier film formed on a columnar surface, and a buried conductive layer that fills the inside of the barrier film. The barrier film may include, but not limited to, at least one of Ti, TIN, Ta, TaN, Ru, Co, Mn, WN, Ni, and NiB. The buried conductive layer may include, but not limited to, at least one of Cu alloys such as Cu, CuSn, CuMg, CuNi, CuZn, CuPd, CuAu, CuRe and CuW, W, W alloys, Ni, Ru, and Co.

In some embodiments, an insulating film may be interposed between the first semiconductor substrate 110 and the first through electrode 130. The insulating film may include, but not limited to, an oxide film, a nitride film, a carbide film, a polymer or a combination thereof.

The first wiring structure 140 may include a metal wiring layer and a via plug. For example, the first wiring structure 140 may be a multilayer structure in which two or more metal wiring layers or two or more via plugs are alternately stacked.

The first lower connecting pad 142 may be disposed on the first semiconductor element layer 120. The first lower connecting pad 142 may be electrically connected to the first wiring structure 140 inside the first semiconductor element layer 120. The first lower connecting pad 142 may be electrically connected to the first through electrode 130 through the first wiring structure 140. The first lower connecting pad 142 may include at least one selected from aluminum (Al), copper (Cu), nickel (Ni), tungsten (W), platinum (Pt), and gold (Au).

The first lower connecting pad 142 may be surrounded by the first upper film 151. The first lower connecting pad 142 may be in contact with the first upper film 151. The first lower connecting pad 142 may be covered with the first upper film 151. The first lower connecting pad 142 may not be in contact with the first lower film 161. The first lower connecting pad 142 may not be surrounded by the first lower film 161.

A first upper connecting pad 144 electrically connected to the first through electrode 130 may be formed on the upper surface of the first semiconductor substrate 110. The first upper connecting pad 144 may be made of the same material as the first lower connecting pad 142. Although not shown, an upper passivation layer may be formed on the upper surface of the first semiconductor substrate 110 to surround a part of the side surface of the first upper connecting pad 144. The upper passivation layer may expose a part of the lower surface of the first upper connecting pad 144.

The first upper connecting pad 144 may be surrounded by the second lower film 162. The first upper connecting pad 144 may be in contact with the second lower film 162. The first upper connecting pad 144 may be covered with the second lower film 162. The first upper connecting pad 144 may not be in contact with the second upper film 152. The first upper connecting pad 144 may not be surrounded by the second upper film 152.

The first connecting bump 170 may be disposed in contact with the first lower connecting pad 142. The first connecting bump 170 may be in direct contact with the upper pad 530. The first lower film 161 may not be disposed between the first connecting bump 170 and the upper pad 530.

The first connecting bumps 170 may electrically connect the first semiconductor chip 100 to the base substrate 500. The first connecting bump 170 may receive at least one of a control signal, a power signal or a ground signal for operating the first to fourth semiconductor chips 100 to 400 from the outside, i.e., from one or more external sources/devices, etc. The first connecting bump 170 may receive a data signal to be stored in the first to fourth semiconductor chips 100 to 400 from the outside, i.e., from one or more external sources/devices, etc. The first connecting bump 170 may provide data stored in the first to fourth semiconductor chips 100 to 400 to the outside. For example, the first connecting bump 170 may include a pillar structure, a ball structure, or a solder layer.

The second semiconductor chip 200 may include a second semiconductor substrate 210, a second semiconductor element layer 220 having a second wiring structure 240, a second through electrode 230, a second lower connecting pad 242, a second upper connecting pad 244, and a second connecting bump 270.

The second semiconductor chip 200 may be disposed on the first semiconductor chip 100. The second semiconductor chip 200 may be electrically connected to the first semiconductor chip 100 through a second connecting bump 270 disposed between the first semiconductor chip 100 and the second semiconductor chip 200.

The third semiconductor chip 300 may be disposed on the second semiconductor chip 200. The third semiconductor chip 300 may include a third semiconductor substrate 310, a third semiconductor element layer 320 having a third wiring structure 340, a third through electrode 330, a third lower connecting pad 342, a third upper connecting pad 344, and a third connecting bump 370.

The fourth semiconductor chip 400 may be disposed on the third semiconductor chip 300. The fourth semiconductor chip 400 may include a fourth semiconductor substrate 410, a fourth semiconductor element layer 420 having a fourth wiring structure 440, a fourth lower connecting pad 442, and a fourth connecting bump 470. The fourth semiconductor chip 400 may not include through electrodes and upper connecting pads, unlike the first to third semiconductor chips 100 to 300.

The second to fourth semiconductor chips 200 to 400 may be substantially the same as or similar to the first semiconductor chip 100. Therefore, detailed description of the second to fourth semiconductor chips 200 to 400 will not be provided.

The base substrate 500 may be, for example, a printed circuit board (PCB), a ceramic substrate or an interposer. Alternatively, the base substrate 500 may be a semiconductor chip including a semiconductor element. The base substrate 500 may function as a support substrate for a semiconductor package. For example, the first to fourth semiconductor chips 100 to 400 described above may be stacked on the base substrate 500.

The base substrate 500 may include a substrate body 510, a lower pad 520, and an upper pad 530. The lower pad 520 may be disposed on the lower surface of the substrate body 510. The upper pad 530 may be disposed on the upper surface of the substrate body 510. External connection terminals 40 may be disposed under the base substrate 500. The external connection terminal 40 may be disposed on the lower pad 520. For example, the external connection terminals 40 may be solder balls or bumps.

The molding film 700 may be formed on the base substrate 500. The molding film 700 may cover the upper film 150, the lower film 160, the base substrate 500, and the first to fourth semiconductor chips 100 to 400. The molding film 700 may include, for example, a polymer such as resin. For example, the molding film 700 may include, but not limited to, EMC (Epoxy Molding Compound).

The molding film 700 may not be disposed between the base substrate 500 and the first semiconductor chip 100. Specifically, since the first upper film 151 and the first lower film 161 are filled between the base substrate 500 and the first semiconductor chip 100, the molding film 700 may not be disposed between the base substrate 500 and the first semiconductor chip 100.

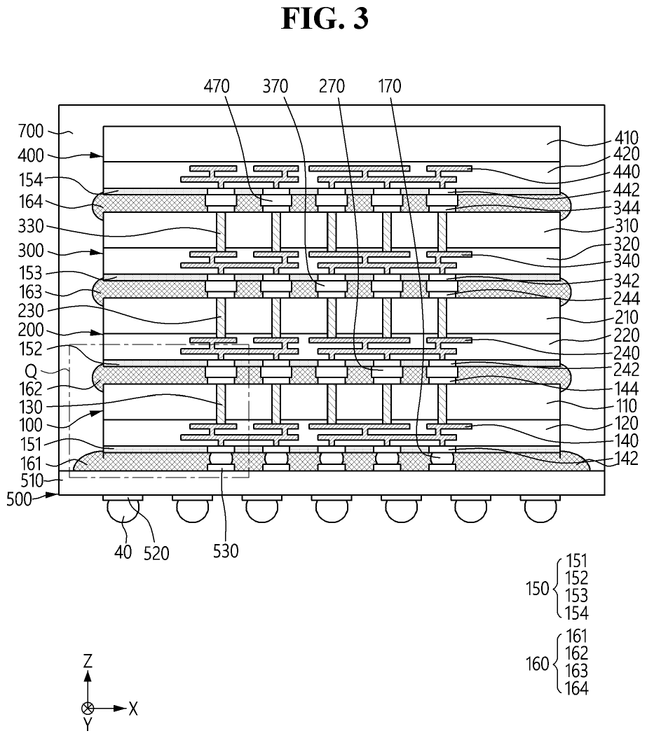

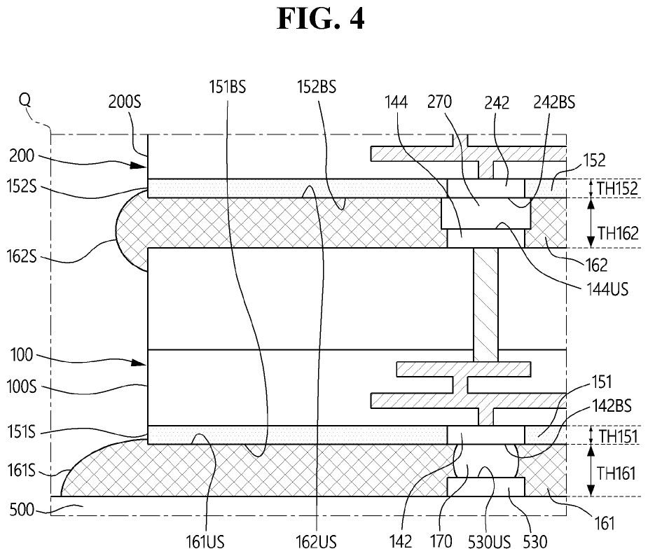

FIG. 3 is a diagram for explaining a semiconductor package according to some other embodiments. FIG. 4 is an enlarged view of a portion Q of FIG. 3. For convenience of explanation, the explanation will focus on points that are different from those explained with reference to FIGS. 1 and 2.

Referring to FIGS. 3 and 4, the lower surface 151BS of the first upper film may be coplanar with the lower surface 142BS of the first lower connecting pad. The first upper film 151 may completely overlap the first lower connecting pad 142 in the first direction X. A thickness TH151 of the first upper film may be the same as the thickness of the first lower connecting pad 142.

The first upper film 151 may not overlap the first connecting bump 170 in the first direction X. The lower surface 151BS of the first upper film may be coplanar with the upper surface of the first connecting bump 170. The first upper film 151 may not be in contact with the first connecting bump 170.

The first lower film 161 may cover a side surface of the first connecting bump 170. The first lower film 161 may surround the side surfaces of the first connecting bump 170. The first lower film 161 may completely overlap the first connecting bump 170 in the first direction X.

The upper surface 161US of the first lower film may be coplanar with the upper surface of the first connecting bump 170. The upper surface 161US of the first lower film may be coplanar with the lower surface 142BS of the first lower connecting pad. The thickness TH161 of the first lower film may be the same as the thicknesses of the first connecting bump 170 and the upper pad 530.

The upper surface 161US of the first lower film may be located above the upper surface 530US of the upper pad. A contact face between the first connecting bump 170 and the upper pad 530 may be disposed inside the first lower film 161. The contact face between the first connecting bump 170 and the upper pad 530 may be disposed between the upper surface 161US of the first lower film and the upper surface of the base substrate 500 in the third direction Z.

The lower surface 152BS of the second upper film may be coplanar with the lower surface 242BS of the second lower connecting pad. The second upper film 152 may completely overlap the second lower connecting pad 242 in the first direction X. The thickness TH152 of the second upper film may be the same as the thickness of the second lower connecting pad 242.

The second upper film 152 may not overlap the second connecting bump 270 in the first direction X. The lower surface 152BS of the second upper film may be coplanar with the upper surface of the second connecting bump 270. The second upper film 152 may not be in contact with the second connecting bump 270.

The second lower film 162 may cover a side surface of the second connecting bump 270. The second lower film 162 may surround the side surface of the second connecting bump 270. The second lower film 162 may completely overlap the second connecting bump 270 in the first direction X.

The upper surface 162US of the second lower film may be coplanar with the upper surface of the second connecting bump 270. The upper surface 162US of the second lower film may be coplanar with the lower surface 242BS of the second lower connecting pad. The thickness TH162 of the second lower film may be the same as the thicknesses of the second connecting bump 270 and the first upper connecting pad 144.

The upper surface 162US of the second lower film may be located above the upper surface 144US of the first upper connecting pad. A contact face between the second connecting bump 270 and the first upper connecting pad 144 may be disposed inside the second lower film 162. The contact face between the second connecting bump 270 and the first upper connecting pad 144 may be disposed between the upper surface 162US of the second lower film and the upper surface of the first semiconductor chip 100 in the third direction Z.

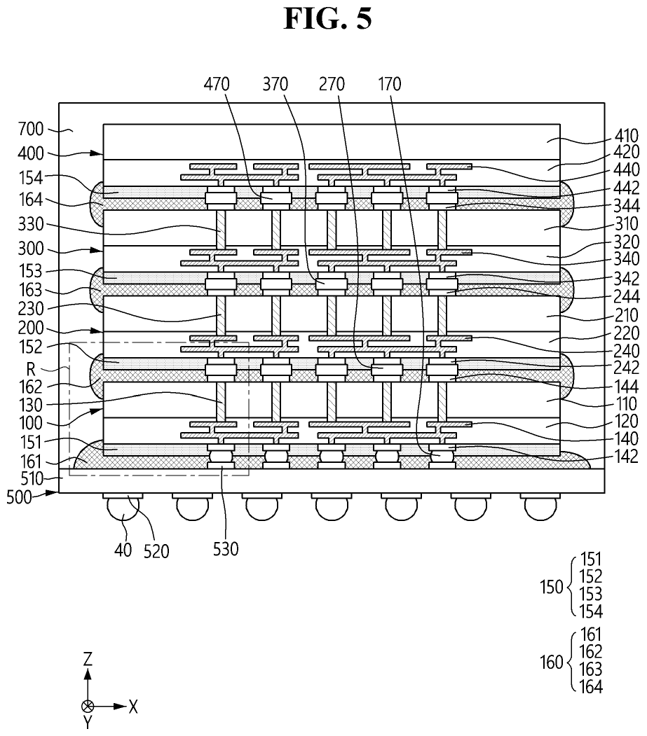

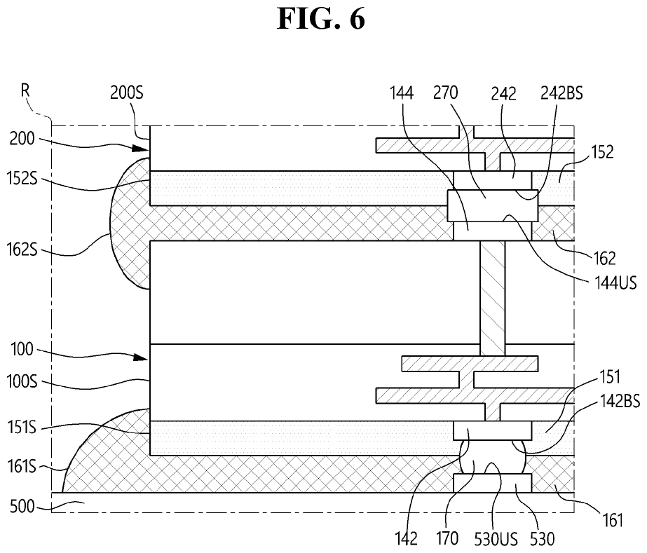

FIG. 5 is a diagram for explaining a semiconductor package according to some other embodiments. FIG. 6 is an enlarged view showing a portion R of FIG. 5. For convenience of explanation, the explanation will focus on points that are different from those described with reference to FIGS. 1 to 4.

Referring to FIGS. 5 and 6, the first lower film 161 may completely cover the side surface 151S of the first upper film. In the first direction X, the first lower film 161 may completely overlap the first upper film 151. The first lower film 161 may overlap the side surface 151S of the first upper film in the first direction X. The uppermost point of the first lower film 161 may be located above the upper surface of the first upper film 151.

The first lower film 161 may cover a part of the side surface 100S of the first semiconductor chip. The first lower film 161 may be in contact with the side surface 100S of the first semiconductor chip. The first lower film 161 may overlap the side surface 100S of the first semiconductor chip in the first direction X. The first lower film 161 may protrude outward beyond the side surface 100S of the first semiconductor chip in the first direction X. The uppermost point of the first lower film 161 may be located above the lower surface of the first semiconductor chip 100.

The second lower film 162 may completely cover the side surface 152S of the second upper film. In the first direction X, the second lower film 162 may completely overlap the second upper film 152. The second lower film 162 may overlap the side surface 152S of the second upper film in the first direction X. The uppermost point of the second lower film 162 may be located above the upper surface of the second upper film 152.

The second lower film 162 may cover a part of the side surface 200S of the second semiconductor chip. The second lower film 162 may be in contact with the side surface 200S of the second semiconductor chip. The second lower film 162 may overlap the side surface 200S of the second semiconductor chip in the first direction X. The second lower film 162 may protrude outward beyond the side surface 200S of the second semiconductor chip in the first direction X. The uppermost point of the second lower film 162 may be located above the lower surface of the second semiconductor chip 200.

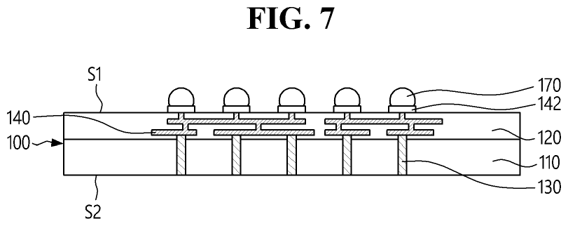

FIGS. 7 to 15 are intermediate stage diagrams showing a method for fabricating a semiconductor package according to some embodiments.

Referring to FIG. 7, the first lower connecting pad 142 and the first connecting bump 170 are formed on the first semiconductor chip 100 including the first semiconductor substrate 110, the first semiconductor element layer 120, and the first through electrode 130.

The first semiconductor chip 100 may include a first face S1 and a second face S2 that are opposite to each other. The first face S1 may correspond to the lower surface of the first semiconductor chip 100. The second face S2 may correspond to the upper surface of the first semiconductor chip 100. The first lower connecting pad 142 and the first connecting bump 170 may be formed on the first face S1 to be connected to the first wiring structure 140.

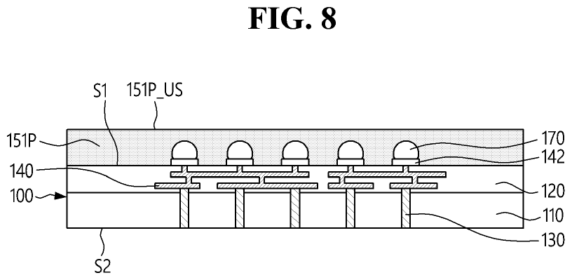

Referring to FIG. 8, a first pre-upper film 151P is formed.

The first pre-upper film 151P may include a photocurable material. For example, the first pre-upper film 151P may be cured by ultraviolet ray.

The first pre-upper film 151P may be formed on the first face S1 of the first semiconductor chip 100. The first pre-upper film 151P may cover the first face S1 of the first semiconductor chip 100. The first pre-upper film 151P may cover the first lower connecting pad 142 and the first connecting bump 170. The first pre-upper film 151P may surround the side surfaces of the first lower connecting pad 142.

The first pre-upper film 151P may completely cover the first connecting bump 170. The first connecting bump 170 may not be exposed from the first pre-upper film 151P. The height to the upper surface 151P_US of the first pre-upper film may be greater than the height to the uppermost face of the first connecting bump 170 on the basis of the first face S1. The upper surface 151P_US of the first pre-upper film may be located above the first connecting bump 170 on the basis of the first face S1.

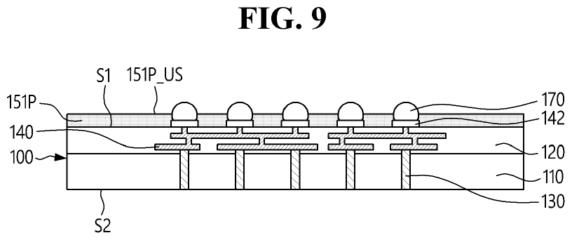

Referring to FIG. 9, a part of the first pre-upper film 151P is removed.

A part of the first pre-upper film 151P may be removed using, for example, a plasma process. A part of the first pre-upper film 151P may be removed through a plasma process that uses carbon tetrafluoride (CF₄) as a process gas.

A part of the first pre-upper film 151P may be removed to expose the first connecting bump 170. The partially removed first pre-upper film 151P may still surround the side surfaces of the first lower connecting pad 142.

The first pre-upper film 151P may not completely cover the first connecting bump 170. The first connecting bump 170 may be exposed from the upper surface 151P_US of the first pre-upper film. The height to the upper surface 151P_US of the first pre-upper film may be smaller than the height to the uppermost face of the first connecting bump 170 on the basis of the first face S1. The upper surface 151P_US of the first pre-upper film may be located below the first connecting bump 170 on the basis of the first face S1.

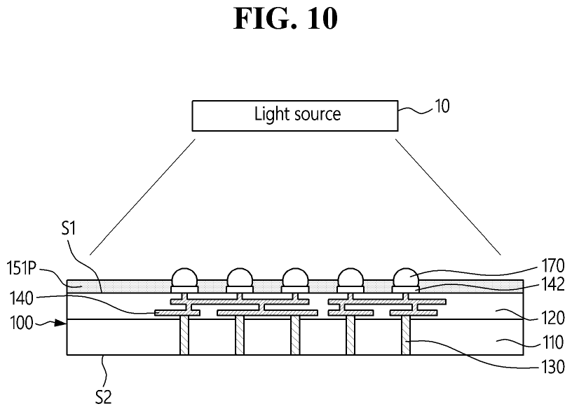

Referring to FIG. 10, the first pre-upper film 151P is cured.

The first pre-upper film 151P may be irradiated with light, using the light source 10. For example, the first pre-upper film 151P may be irradiated with ultraviolet ray. The first pre-upper film 151P may be irradiated with light on the first face S1 of the first semiconductor chip 100. The first pre-upper film 151P may be cured on the first face S1 of the first semiconductor chip 100.

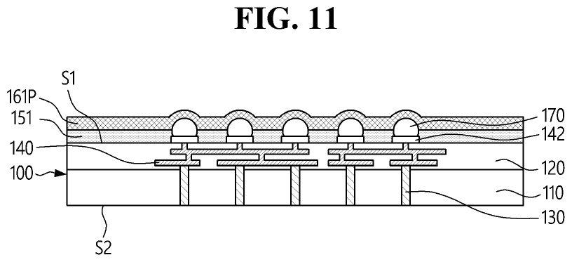

Referring to FIG. 11, a first pre-lower film 161P is formed.

The first upper film 151 may be formed by curing the first pre-upper film (151P of FIG. 10). The first pre-lower film 161P may be formed on the first face S1 of the first semiconductor chip 100.

The first pre-lower film 161P may be formed on the first upper film 151. The first pre-lower film 161P may extend along the surface of the first upper film 151. The first pre-lower film 161P may cover the first connecting bumps 170 exposed from the first upper film 151.

The first connecting bump 170 may not be exposed from the first pre-lower film 161P. The height to the uppermost face of the first pre-lower film 161P may be greater than the height to the uppermost face of the first connecting bump 170 on the basis of the first face S1. The uppermost face of the first pre-lower film 161P may be located above the uppermost face of the first connecting bump 170 on the basis of the first face S1.

The first pre-lower film 161P may extend along the surface of the first connecting bump 170 exposed from the first upper film 151. Although FIG. 11 shows that the first pre-lower film 161P has a curved surface along the profile of the first connecting bump 170, the embodiment is not limited thereto. For example, the first pre-lower film 161P may have a flat surface on the first connecting bump 170.

The first pre-lower film 161P may not be in contact with the first lower connecting pad 142. An interface between the first pre-lower film 161P and the first upper film 151 may be located above the first lower connecting pad 142.

The first pre-lower film 161P may include a thermosetting material. For example, the first pre-lower film 161P may decrease in viscosity at a certain temperature when the temperature gradually increases, and may increase in viscosity as the temperature increases again.

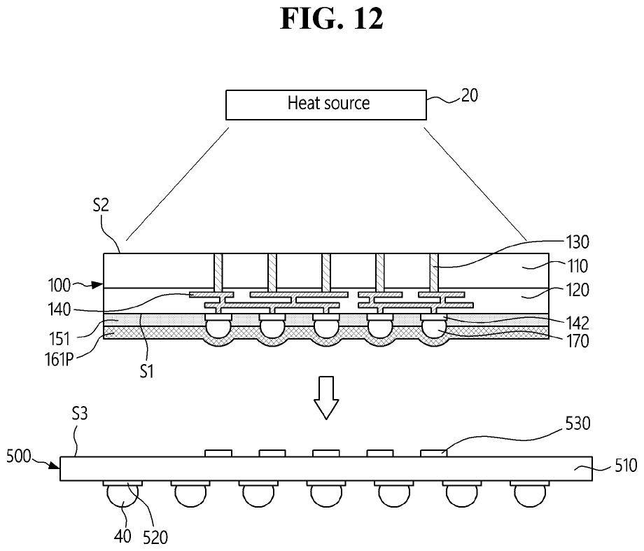

Referring to FIG. 12, the first pre-lower film 161P is cured, and the first semiconductor chip 100 may be bonded onto the package substrate 500.

The first semiconductor chip 100 may be disposed on the package substrate 500 such that the first face S1 of the first semiconductor chip 100 faces a third surface S3 of the package substrate 500.

The upper pad 530 may be formed on the third surface S3 of the package substrate 500. The third surface S3 of the package substrate 500 may correspond to the upper surface of the package substrate 500.

Heat may be provided to the first pre-lower film 161P through the heat source 20. When the first semiconductor chip 100 is stacked on the package substrate 500, heat and pressure may be applied. The provided heat may change the viscosity of the first pre-lower film 161P. For example, while heat is provided to increase the temperature, the viscosity of the first pre-lower film 161P may be the lowest at a particular temperature. The provided pressure may press the first semiconductor chip 100 to be bonded onto the package substrate 500. The first pre-lower film 161P, which has a lower viscosity, may not be disposed between the first connecting bump 170 and the upper pad 530. The first pre-lower film 161P, which has a lower viscosity, flows laterally when the first connecting bump 170 and the upper pad 530 are bonded together.

Although heat is shown to be provided to the second face S2 of the first semiconductor chip 100 through the heat source 20, the embodiment is not limited thereto. For example, heat may be applied to the first face S1 of the first semiconductor chip 100 that faces the third surface S3 of the package substrate 500.

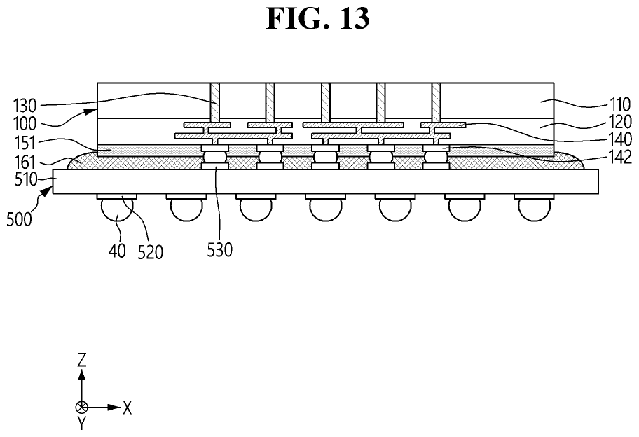

Referring to FIG. 13, the first lower film 161 is formed, and the first semiconductor chip 100 is attached onto the package substrate 500.

The first lower film 161 may protrude outward beyond the side surface of the first semiconductor chip 100. The first lower film 161 may protrude outward beyond the side surface of the first upper film 151. Specifically, the first pre-lower film (161P of FIG. 12) whose viscosity has decreased due to heat may protrude outward beyond the side surface of the first semiconductor chip 100 or the side surface of the first upper film 151, while flowing laterally when the first connecting bump 170 and the upper surface pad 530 are bonded together.

Since the first upper film 151 has already been irradiated with light and cured before the first pre-lower film (161P of FIG. 11) is formed, it may not flow when the first connecting bump 170 and the upper pad 530 are bonded together. Therefore, the first upper film 151 may not protrude outward beyond the side surface of the first semiconductor chip 100.

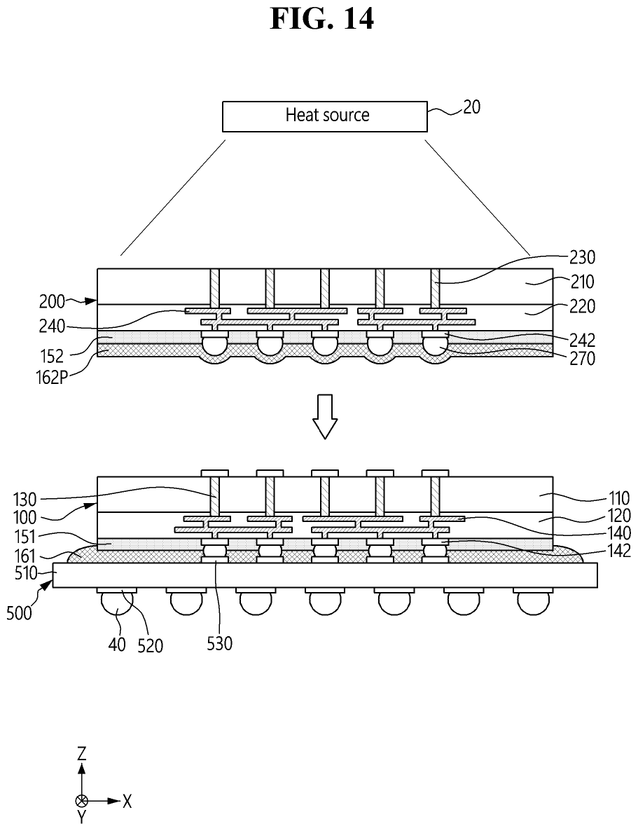

Referring to FIG. 14, the second semiconductor chip 200 is stacked on the first semiconductor chip 100 while receiving heat.

Similarly to the first upper film 151, the second upper film 152 is cured by receiving light before the second pre-lower film 162P is formed. The second pre-lower film 162P may be attached onto the first semiconductor chip 100 while being cured by receiving heat.

The second semiconductor chip 200 may be disposed on the first semiconductor chip 100 such that the second pre-lower film 162P faces the upper surface of the first semiconductor chip 100. Heat may be provided to the first pre-lower film 161P through the heat source 20. When the first semiconductor chip 100 is stacked on the package substrate 500, heat and pressure may be applied.

Heat may be provided to the second pre-lower film 162P through the heat source 20. When the second semiconductor chip 200 is stacked on the first semiconductor chip 100, heat and pressure may be provided. The provided heat may change the viscosity of the second pre-lower film 162P.

The pressure provided may press the second semiconductor chip 200 to be bonded onto the first semiconductor chip 100. The second pre-lower film 162P, which has a lower viscosity, may not be disposed between the second connecting bump 270 and the first upper connecting pad 144. The second pre-lower film 162P, which has a lower viscosity, may flow laterally, when the second connecting bump 270 and the first upper connecting pad 144 are bonded together.

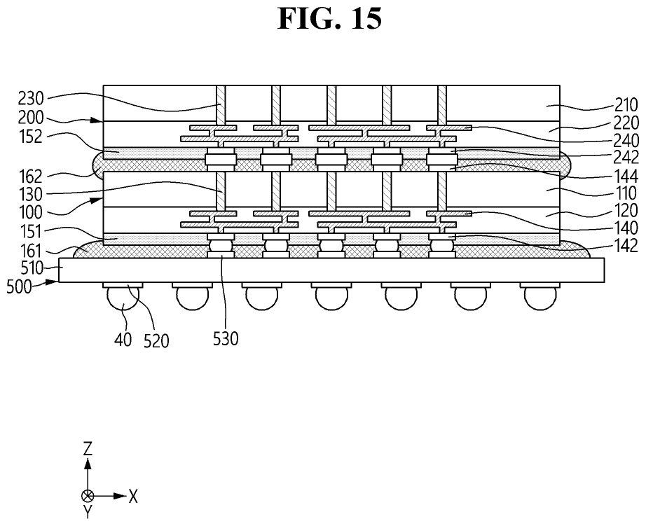

Referring to FIG. 15, the second lower film 162 is formed and the second semiconductor chip 200 is attached onto the first semiconductor chip 100.

The second lower film 162 may protrude outward beyond the side surface of the second semiconductor chip 200. The second lower film 162 may protrude outward beyond the side surface of the second upper film 152.

Next, referring to FIG. 1, similarly to the first semiconductor chip 100 and the second semiconductor chip 200, the third semiconductor chip 300 may be attached onto the second semiconductor chip 200 through the third upper film 153 and the third lower film 163. Similarly, the fourth semiconductor chip 400 may be attached onto the third semiconductor chip 300 through the fourth upper film 154 and the fourth lower film 164.

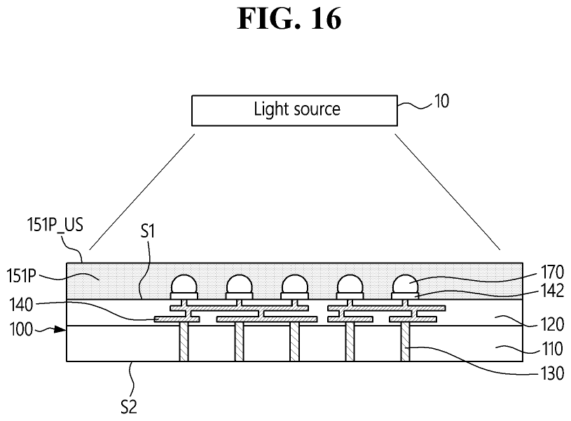

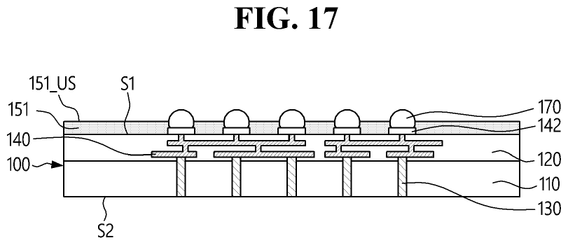

FIGS. 16 and 17 are diagrams of intermediate steps for explaining a method for fabricating a semiconductor package according to some other embodiments. For reference, FIG. 16 is a diagram showing the steps after FIG. 8. For convenience of explanation, the explanation will focus on the points that are different from those explained with reference to FIGS. 7 to 15.

Referring to FIGS. 8 and 16, the first pre-upper film 151P that completely covers the first connecting bump 170 is cured.

When the first pre-upper film 151P is cured, the first connecting bump 170 may not be exposed from the first pre-upper film 151P.

Referring to FIG. 17, a part of the cured first upper film 151 is removed.

After the first upper film 151 is cured on the first face S1 of the first semiconductor chip 100, a part of the first upper film 151 may be removed so that the first connecting bumps 170 are exposed.

The first upper film 151 may be partially removed, for example, using a plasma process. The first upper film 151 may be partially removed through the plasma process that uses carbon tetrafluoride (CF₄) as a process gas.

In concluding the detailed description, those skilled in the art will appreciate that many variations and modifications may be made to the embodiments without substantially departing from the principles of the present inventive concept. Therefore, the disclosed embodiments of the disclosure are used in a generic and descriptive sense only and not for purposes of limitation.

What is claimed is:

1. A semiconductor package comprising:
a base substrate;
a first semiconductor chip on the base substrate;
a second semiconductor chip on the first semiconductor chip;
an upper pad on an upper surface of the first semiconductor chip;
a lower pad on a lower surface of the second semiconductor chip, wherein the lower surface of the second semiconductor chip faces the upper surface of the first semiconductor chip;
a connecting bump between the upper pad and the lower pad;
a lower film on the upper surface of the first semiconductor chip, and on a side surface of the upper pad; and
an upper film between the lower film and the lower surface of the second semiconductor chip, and on a side surface of the lower pad,
wherein the lower film comprises a thermosetting material,
the upper film comprises a photocurable material, and
a side surface of the lower film protrudes outward beyond a side surface of the first semiconductor chip.

2. The semiconductor package of claim 1,
wherein the lower film is on a side surface of the upper film.

3. The semiconductor package of claim 1,
wherein an upper surface of the lower film is above an upper surface of the upper pad, and
the upper surface of the lower film is below a lower surface of the lower pad.

4. The semiconductor package of claim 1,
wherein a side surface of the second semiconductor chip does not protrude beyond the side surface of the lower film.

5. The semiconductor package of claim 1,
wherein an upper surface of the lower film is on a same plane as or below a lower surface of the lower pad.

6. The semiconductor package of claim 1,
wherein a side surface of the upper film is coplanar with a side surface of the second semiconductor chip.

7. The semiconductor package of claim 1,
wherein the side surface of the lower film protrudes outward beyond a side surface of the upper film.

8. The semiconductor package of claim 1,
wherein the lower film is on a side surface of the second semiconductor chip.

9. The semiconductor package of claim 1,
wherein a side surface of the connecting bump is in contact with the lower film and the upper film.

10. The semiconductor package of claim 1,
wherein the lower film extends around a side surface of the connecting bump.

11. The semiconductor package of claim 1,
wherein the first semiconductor chip comprises a through electrode that penetrates the first semiconductor chip.

12. The semiconductor package of claim 1, further comprising:
a molding film on the base substrate, the first semiconductor chip, and the second semiconductor chip.

13. A semiconductor package comprising:
a base substrate;
a first semiconductor chip on the base substrate;
a second semiconductor chip on the first semiconductor chip;
a first upper pad on an upper surface of the first semiconductor chip;
a first lower pad on a lower surface of the second semiconductor chip, wherein the lower surface of the second semiconductor chip faces the upper surface of the first semiconductor chip;
a first connecting bump between the first upper pad and the first lower pad;
a first lower film on the upper surface of the first semiconductor chip, and on a side surface of the first upper pad, wherein the first lower film comprises a thermosetting material; and
a first upper film between the first lower film and the lower surface of the second semiconductor chip, and on a side surface of the first lower pad, wherein the first upper film comprises a photocurable material,
wherein a maximum width of the first lower film is greater than a maximum width of the first upper film.

14. The semiconductor package of claim 13,
wherein a side surface of the second semiconductor chip does not protrude beyond a side surface of the first lower film.

15. The semiconductor package of claim 13,
wherein a side surface of the first upper film is coplanar with a side surface of the second semiconductor chip, and
a side surface of the first lower film protrudes outward beyond the side surface of the first upper film.

16. The semiconductor package of claim 13,
wherein the first upper pad and the first lower pad have a same width.

17. The semiconductor package of claim 13, further comprising:
an upper substrate pad on an upper surface of the base substrate, wherein the upper surface of the base substrate faces a lower surface of the first semiconductor chip;
a second lower pad on the lower surface of the first semiconductor chip;
a second connecting bump between the upper substrate pad and the second lower pad;
a second lower film on the upper surface of the base substrate, and on a side surface of the upper substrate pad, wherein the second lower film comprises a thermoset material; and
a second upper film between the second lower film and the lower surface of the first semiconductor chip, and on a side surface of the second lower pad, wherein the second upper film comprises a photocurable material.

18. The semiconductor package of claim 17,
wherein a side surface of the second lower film protrudes outward beyond a side surface of the second upper film.

19. The semiconductor package of claim 13,
wherein the first connecting bump and the first upper pad are in direct contact with each other.

20. A semiconductor package comprising:
a base substrate;
a first semiconductor chip on the base substrate;
a second semiconductor chip on the first semiconductor chip;
a first upper pad on an upper surface of the first semiconductor chip;
a first lower pad on a lower surface of the second semiconductor chip, wherein the lower surface of the second semiconductor chip faces the upper surface of the first semiconductor chip;
a first connecting bump between the first upper pad and the first lower pad;
a first lower film on the upper surface of the first semiconductor chip, and on a side surface of the first upper pad, wherein the first lower film comprises a thermosetting material;
a first upper film between the first lower film and the lower surface of the second semiconductor chip, and on a side surface of the first lower pad, wherein the first upper film comprises a photocurable material; and
a molding film on the base substrate, the first semiconductor chip, and the second semiconductor chip,
wherein a side surface of the first upper film is coplanar with a side surface of the second semiconductor chip,
a side surface of the first lower film protrudes outward beyond the side surface of the first upper film, and
an upper surface of the first lower film is below a lower surface of the first lower pad.
